(19) United States
(12) Patent Application Publication
(10) Pub. No.: US 2007/0218199 A1
(43) Pub. Date: Sep. 20, 2007

(54) Crucible eliminating line of sight between a source material and a target

(75) Inventors: Richard Charles Bresnahan, Cottage Grove, MN (US); David William Gotthold, Lino Lakes, MN (US); Scott Wayne Priddy, St. Louis Park, MN (US)

Correspondence Address: KAGAN BINDER, PLLC, SUITE 200, MAPLE ISLAND BUILDING, 221 MAIN STREET NORTH, STILLWATER, MN, 55082, US

(73) Assignee: Veeco Instruments Inc.

(21) Appl. No.: 11/353,708

(22) Filed: Feb. 13, 2006

(51) Int. Cl. C23C 16/00

(52) U.S. Cl. 427/248.1; 118/726

(57) ABSTRACT

A crucible for heating material to be deposited on a target substrate includes a body configured to contain source material, a base formed at a first end of the body, and an emitting orifice formed at a second end of the body. The crucible further includes at least one intermediate orifice arranged and configured such that the heated source material passes through the intermediate orifice and impacts at least once upon the inner surface of the crucible body before passing through the emitting orifice.

### TECHNICAL FIELD

The invention is directed to a crucible for holding material to be deposited on a substrate and, in particular, to an improved crucible configuration for eliminating the line of sight between a source material and a target.

### BACKGROUND

Molecular beam epitaxy (MBE) is a growth process involving the deposition of thin films of one or more source materials onto a substrate in a vacuum by directing molecular or atomic beams of the source material onto the substrate. In some MBE processes, the deposited source material atoms and molecules come to rest on the substrate to form a crystal structure. MBE is widely used in compound semiconductor research and in the semiconductor device fabrication industry, for thin-film deposition of elemental semiconductors, metals and insulating layers.

A principal apparatus utilized in MBE deposition is an effusion cell, which includes a crucible and a heating source. The crucible contains the source material, which is the source of the atoms and molecules that form the molecular beam. Referring to FIG. 1, one example of a typical crucible system 100 of the prior art is illustrated. The prior crucible system 100 includes a crucible 110 and a heating element 160. The crucible 110 includes a base 115 and a body 125 extending from the base 115 and ending in an emitting orifice 120. The emitting orifice 120 has a width or diameter D1. The crucible 110 retainably holds a source material 180 proximate the base 115. The source material 180 is heated and vaporized by heating the crucible 110 with the heating element 160, thereby causing the vaporized source material 180 to effuse out of the crucible 110.

Prior crucibles, however, have significant limitations. Some prior crucible designs can lead to defects in the thin film formed during the MBE process. These defects may be the result of non-uniform deposition, or the result of unintended deposition of contaminants or larger clusters of molecules.

Uniformity relates primarily to the uniformity of the density and thickness of the layers deposited over the target substrate via the material emitted from the orifice of the crucible. Uniformity may also be compositional when, for example, multiple materials are codeposited with different individual uniformities.

Some examples of crucible related defects are thought to be caused by spitting from the material melt within the crucible which occurs when droplets of condensed material form on the crucible wall adjacent the crucible-emitting orifice and then roll back into the melt. These condensed droplets, when heated by the melt, can be effused out of the emitting orifice towards the substrate as large molecules. Material condenses at the emitting orifice due to a reduced temperature in the emitting orifice region. This is especially problematic for compound source materials such as CdTe, but may also affect elemental sources as well.

Defect production has been reduced in some crucible designs by heating the crucible walls adjacent the emitting orifice (i.e., or lip) of the crucible to prevent material condensation. Such designs are commonly referred to as “hot lip sources”. Problems with some hot lip crucible designs include a tendency of producing a hydrodynamically unstable flux, a tendency to produce undesirable levels of impurities, and the frequent exhibition of depletion effects.

In some conventional crucibles designs, a baffle is inserted within the emitting orifice to “crack” large molecules (i.e., polyatomic molecules) into simpler molecules or atoms. Cracking refers to the transfer of thermal energy from a heated surface to large molecules of source material when the large molecules contact the surface. Although this design represents an advance over other conventional crucibles, it appears to have a shortcoming. The baffle is generally heated via conduction or radiation from the crucible, instead of directly from a heater. The baffle, therefore, is typically at a lower temperature than the crucible. When the large molecules impact upon the baffle surface, the thermal energy of the baffle is transferred to the large molecules. The lower the temperature of the impacted surface, however, the lower the probability that a polyatomic molecule will crack into simpler molecules.

There remains a need for new crucible designs.

### SUMMARY

The invention relates to a crucible for containing source material to be deposited on a substrate to form a thin layer of deposited material. The crucible includes a body extending between a base and an emitting orifice. A heating source heats the crucible to vaporize the source material. The emitting orifice of the crucible is aimed in the direction of the substrate on which the source material is to be deposited.

According to some embodiments of the invention, the crucible includes at least one intermediate orifice arranged and configured within the crucible such that the source material, when heated, passes through the intermediate orifice before passing through the emitting orifice.

According to other embodiments of the invention, the crucible includes at least one intermediate orifice such that, when heated, atoms and molecules of the source material impact at least once upon the body of the crucible before passing through the emitting orifice.

According to another embodiment of the invention, the crucible includes an intermediate orifice configured as a neck orifice.

According to yet still other embodiments of the invention, the crucible includes multiple intermediate orifices.

According to one embodiment of the invention, a crucible for heating material to be deposited on a substrate includes a body arranged and configured to contain source material, a base formed at a first end of the body, and an emitting orifice formed at a second end of the body. The crucible further includes at least one intermediate orifice arranged and configured such that the heated source material passes through the intermediate orifice and impacts at least once upon the body before passing through the emitting orifice.

One feature of the invention includes a transference of thermal energy from the crucible body to atoms and molecules desorbing from the crucible body.

Another feature of the invention includes an improvement in the uniformity of the thin layer of material formed during deposition.

Yet another feature of the invention is that the crucible configuration reduces the probability of source material spitting from the crucible during deposition.

Still yet another feature of the invention is an increase in the molecule cracking efficiency of the crucible.

### BRIEF DESCRIPTION OF THE DRAWINGS

Referring now to the drawings in which like reference numbers represent corresponding parts throughout:

FIG. 1 illustrates one example of a conventional crucible design.

FIG. 2 illustrates an example MBE deposition system including multiple source material containing crucibles aimed at a substrate.

FIG. 3 illustrates a diagrammatic view of an epitaxial layer being formed on a substrate.

FIG. 4 illustrates a diagrammatic view of an epitaxial layer including defects being formed on a substrate.

FIG. 5 illustrates a partial perspective view of one example embodiment of a crucible configured according to the present disclosure.

FIG. 6 illustrates a schematic cross-sectional view of another example embodiment of a crucible configured according to the present disclosure.

FIG. 7 illustrates a schematic cross-sectional view of another example embodiment of a crucible configured according to the present invention.

FIG. 8 illustrates a schematic diagram of the path of an atom desorbing from a surface at an angle.

FIGS. 9A and 9B illustrate schematics depicting the highest probability of desorption paths from first and second inner surfaces, respectively, of a crucible body according to one embodiment of the present disclosure.

### DETAILED DESCRIPTION

The invention is directed to a crucible for heating source material to be deposited on a substrate to form a thin film. The crucible includes a body enclosing an interior space. The body extends from a base to an emitting orifice. Source material is typically held within the interior space proximate the base. A heating source heats the crucible, which heats the source material contained therein. The emitting orifice of the crucible is aimed at a substrate on which the source material is to be deposited.

According to one embodiment of the invention, the crucible includes at least one intermediate orifice arranged and configured such that the source material, when heated, passes through the intermediate orifice before passing through the emitting orifice. According to another embodiment, the crucible includes at least one intermediate orifice such that, when heated, the source material impacts at least once upon the body of the crucible. According to yet another embodiment, the crucible includes multiple intermediate orifices. According to still yet another embodiment, thermal energy is transferred from the inner surface of the crucible to atoms and molecules impacting on the inner surface.

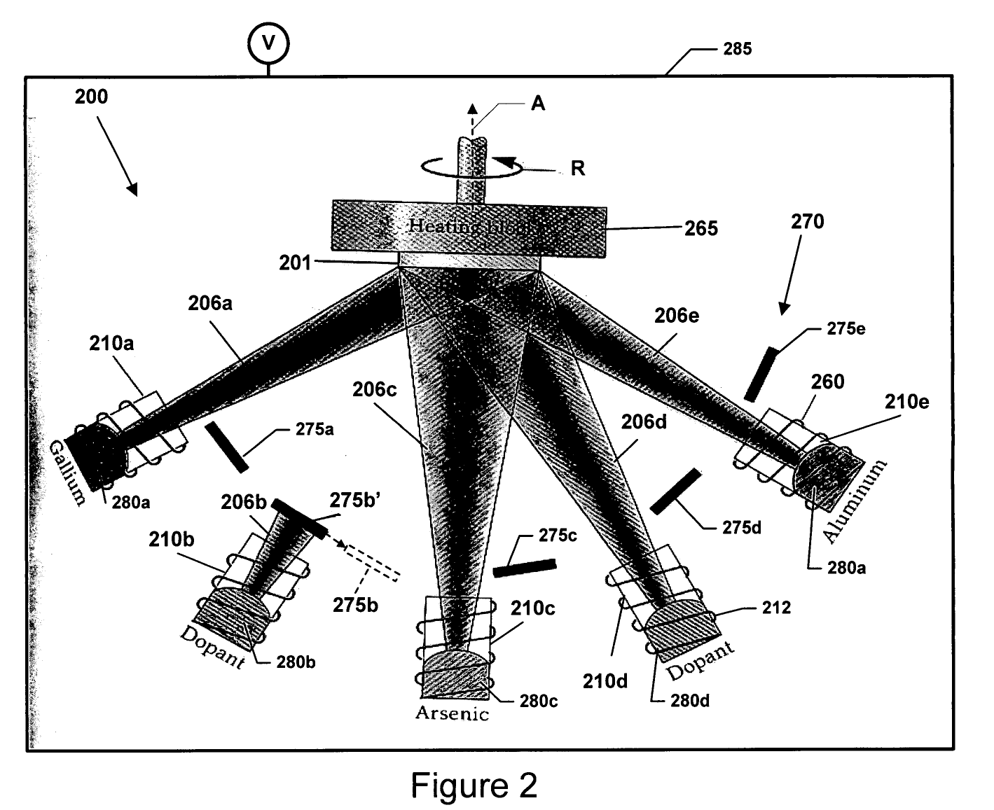

Referring to FIG. 2, the crucible can be used to perform Molecular Beam Epitaxy (MBE). FIG. 2 illustrates an example MBE deposition system 200 including multiple crucibles diagrammatically illustrated at 210, aimed at a substrate 201. Of course, other examples of an MBE system may include only one crucible. The crucible(s) 210 and substrate 201 are oriented within an ultra high vacuum growth chamber 285, which is evacuated by a vacuum pump V to an appropriate pressure, as is well known in the art.

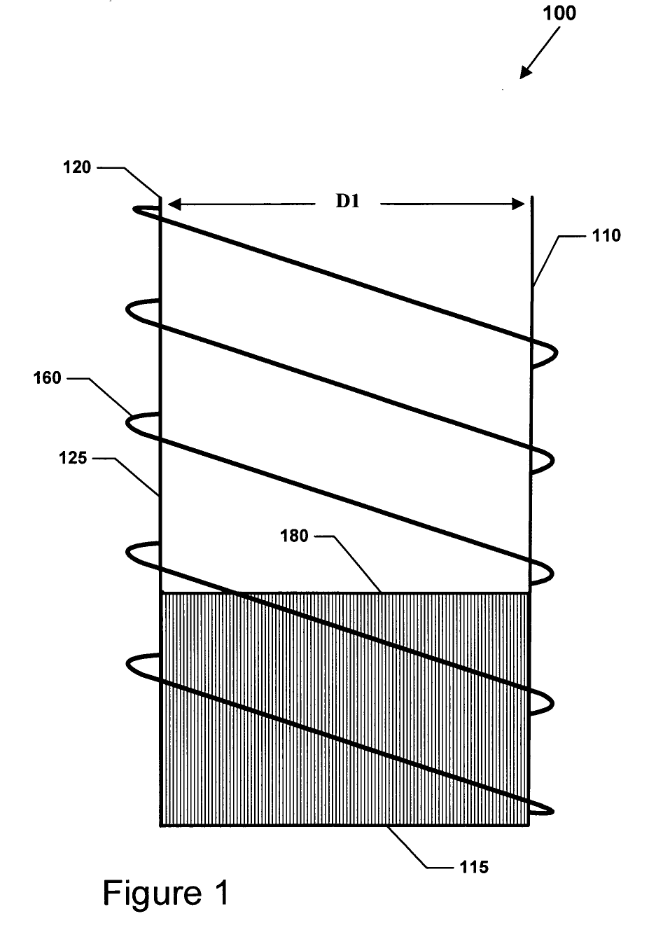

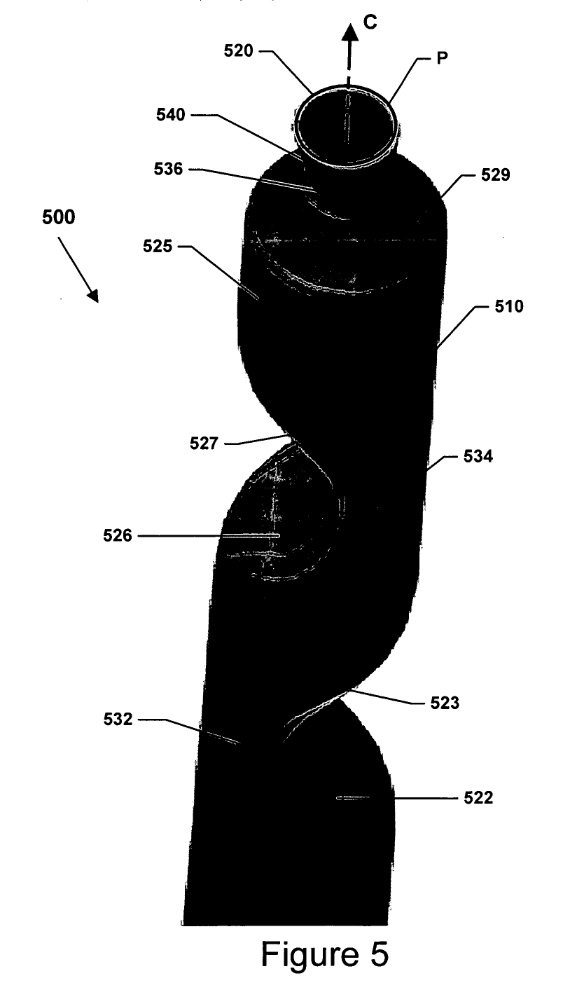

The crucibles 210 vaporize and direct “beams” 206 of atoms or molecules of the source material 280 into the ultra high vacuum growth chamber 285 for deposit on the substrate 201. Aiming the beams 206 of source material 280 includes positioning and orienting the crucibles 210 containing the source material 280 such that the beam-emitting orifice of each crucible 210 is “aimed” at the substrate 201. The emitting orifice of a conventional crucible 110 is illustrated at 120 in FIG. 1. The emitting orifice of a crucible configured according to the principles of this invention, such as crucible 510 in FIG. 5, is hereinafter described in more detail.

In some embodiments of MBE systems, the substrate 201 is coupled to a heating block 265 and rotated continuously around an axis A in a direction of rotation R in order to promote uniform crystal growth on the surface of the substrate 201. Each of the source materials 280 is heated using a heating element generally illustrated at 260. Generally, the source material 280 is heated by heating the crucible 210. One example of a heating element 260 includes heating coils 212 contacting the crucible 210. Another example of a heating element 260 includes a resistive filament (not shown), which radiates heat to the crucible 210. Yet another example of a heating element 260 includes an effusion cell oven (not shown) enclosing the crucible 210. Of course, any suitable heating means as known by those skilled in the art can also be used. Heating the crucible 210 vaporizes the source material 280 through either an evaporation process or a sublimation process. In some cases, heating the crucible 210 also prevents condensation of the source material vapor within the crucible 210. After growth or deposition is completed, the formed wafer or product is cooled and removed from the chamber 285.

Generally, the temperature to which each source material is heated is based on the vapor pressure of the source material in addition to specific properties of the source material. For example, when forming a thin film product from arsenic, it may be advantageous to break down large As₄ molecules (i.e., four arsenic atoms covalently bonded to each other) into smaller As₂ molecules (i.e., two arsenic atoms covalently bonded to each other). Arsenic typically sublimates around 400° C. as As₄ molecules, but further heating of the As₄ molecular vapor up to about 900° C. begins to break the bonds of each As₄ molecule to form two As₂ molecules. For this type of source, multiple filaments are used to set up a thermal gradient along the crucible to heat the arsenic in the base of the crucible to around 400° C. and the tip of the crucible to around 900° C.

Still referring to FIG. 2, five crucibles 210a-210e are shown in the illustrated example system 200. Each crucible 210a-210e contains a different source material 280a-280e, from which a molecular beam 206a-206e is generated. In one example embodiment, the first crucible 210a contains Gallium, the second crucible 210b contains a first dopant, the third crucible 210c contains Arsenic, the fourth crucible 210d contains a second dopant, and the fifth crucible 210e contains Aluminum.

In some embodiments, adjusting the evaporation rate of the source material controls the quantity of atoms or molecules in the molecular beam. The evaporation rate depends on the temperature of the heater and the composition of the source material. In addition, some example crucibles have a modulating valve that adjusts the conductance of the source from the crucible. In still other embodiments, shutters in front of each crucible control which atoms or molecules are allowed to reach the substrate. In one example embodiment, atoms or molecules that are blocked by the shutter are then “redirected” away from the substrate.

For example, the system 200 shown in FIG. 2 includes a shutter system schematically illustrated at 270. The shutter system includes one or more shutters 275. Each shutter 275 of the shutter system 270 can move between a first, closed position and a second, open position. When in the closed position, a shutter 275 blocks a molecular beam 206 effusing from a crucible from reaching the substrate 201. When in the open position, the shutter 275 enables the molecular beam 206 to deposit the source material 280 upon the substrate 201.

For example, the shutter system 270 shown in the illustrated system 200 includes a shutter 275a-275e corresponding to each crucible 210a-210e, respectively. The shutter corresponding to the crucible 210b that contains the first dopant is shown in a first, closed position at 275b′ and, in dashed lines, in a second, open position at 275b. The remaining shutters 275a, 275c, 275d, 275e of shutter system 270 are shown in an open position. The closed shutter 275b′ blocks the molecular beam 206b from reaching the substrate 201, whereas the open shutters 275a, 275c, 275d, 275e enable the molecular beams 206a, 206, 206d, 206e to impinge upon the substrate 201 and form doped aluminum gallium arsenide.

In various example systems, source materials, such as the source materials 280 of FIG. 2, may include various elements in a solid, liquid, and/or gaseous phase. Example liquid source materials include gallium, indium, and mercury. Example solid source materials include arsenic, tellurium, and silicon. Example gaseous source materials include nitrogen and ammonia.

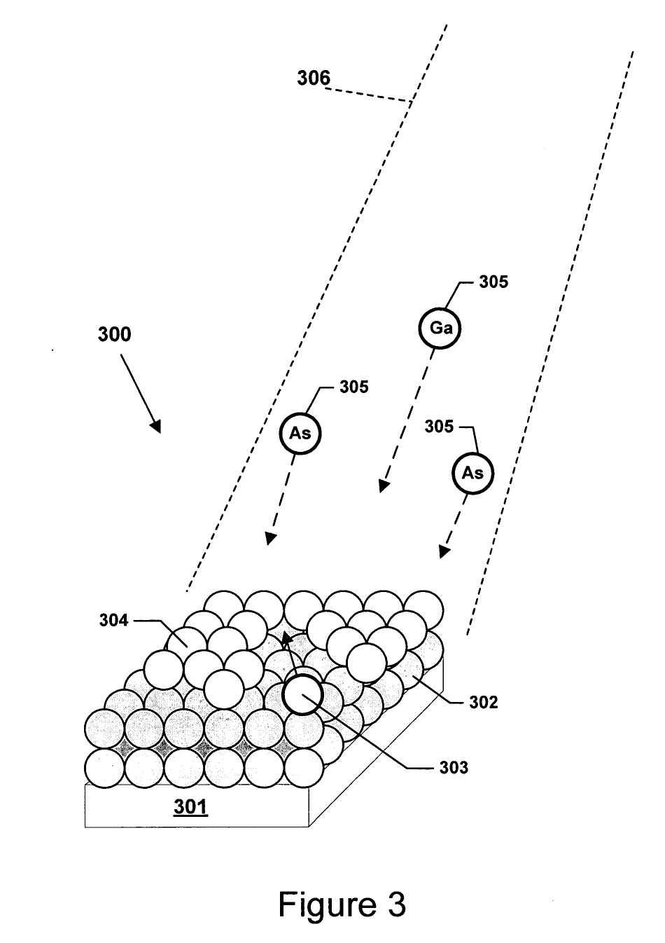

Referring to FIG. 3, FIG. 3 illustrates a diagram of a deposition system 300 including an epitaxial layer 302 formed on a substrate 301. Molecules or atoms 305 formed from heating a source material, such as the source material 280 of FIG. 2, are added to the epitaxial layer 302 via one or more molecular beams 306. These atoms and molecules 305 form a growing epitaxial layer 304 on top of the previously formed epitaxial layer 302. Typically, deposited atoms and molecules 303 migrate to energetically preferred lattice positions on the substrate 301, theoretically yielding film growth of high crystalline quality, and thickness uniformity.

The greater the energy of the atoms and molecules 305, the higher the probability of the atoms and molecules 305 finding optimum lattice positions within the crystal structure forming on the substrate 301. Generally, after arriving at the substrate 301, atoms and molecules 305 having higher energy levels can move further along the surface of the substrate 301 to find a proper resting site. Increasing the energy of the deposited atoms and molecules 305, therefore, decreases the probability of defects occurring in misalignment of the atoms within the crystal structure.

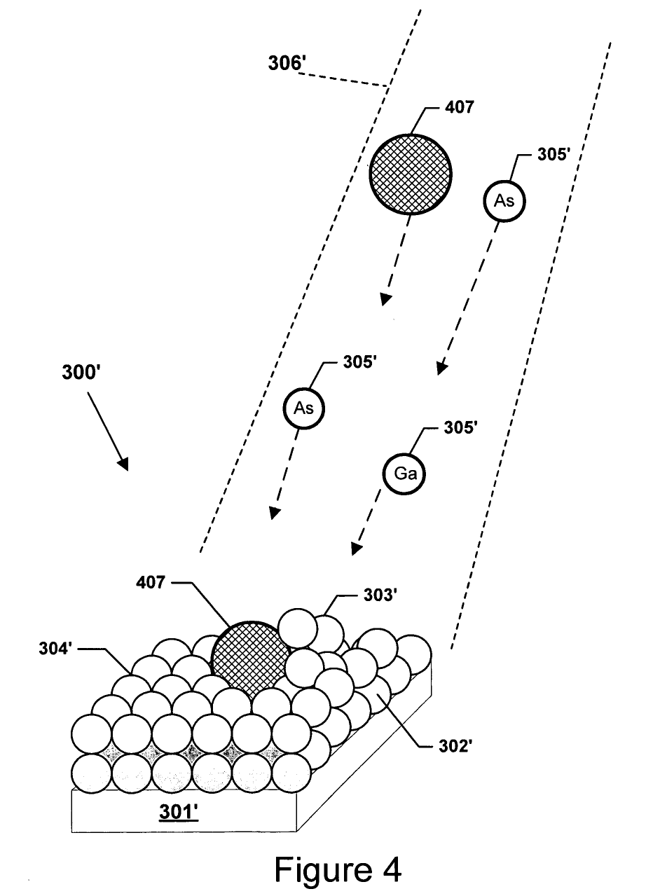

Referring now to FIG. 4, defects in a crystalline structure can also occur in the epitaxial layer when larger or unintended molecules impinge on the substrate. FIG. 4 illustrates a diagram 300′ of an epitaxial layer 302′ formed on a substrate 301′. Diagram 300′ is similar to diagram 300 of FIG. 3, with like parts between FIGS. 3 and 4 carrying the same numerical designations with an additional prime (′) designator in FIG. 4, except that the molecular beam 306′ includes large molecules 407 as well as atoms and smaller molecules 305′.

Generally, particles, such as large molecules 407, spit (i.e., ejected) from crucibles of known construction in the art that have an emitting orifice aimed at the substrate will generally hit the substrate. Some of these particles may stick to the substrate or forming epitaxial layer, leading to defects in the crystal structure. For example, the large molecules 407 of FIG. 4 are shown impinging upon the epitaxial layer 302′ and interfering with the formation of the growing layer 304′. In some cases, the large molecules 407 may impede atoms 303′ from migrating to and occupying a preferred lattice position within the growing layer 304′.

Spitting is one source of large molecules, such as large molecules 407, in a molecular beam. In some cases, spitting results from impure source material. For example, if a crucible contains source material including cadmium and tellurium in compound form (i.e., CdTe), pockets or chunks of pure tellurium and cadmium can exist within the compound. Generally, CdTe has a significantly lower vapor pressure (10⁻⁴ Torr @ 450° C.) than either tellurium (10⁻⁴ Torr ® 280° C.) or cadmium (10⁻⁴ Torr @ 177° C.). Therefore, when pockets of cadmium or tellurium are exposed by the evaporation of the CdTe compound around the pockets, the pockets may evaporate quickly and explosively. Such an explosion can cause physical ejection of chunks of source material.

Referring now to FIG. 5, the present invention generally eliminates a line of sight between the source material within the crucible and the substrate, which reduces the possibility of particles generated in the source material, such as the large particles 407 of FIG. 4, reaching the substrate. FIG. 5 illustrates a partial perspective view of one example embodiment 500 of a crucible 510. The crucible 510 includes a body 525 defining an emitting orifice 520. The body 525 defines therewith an internal cavity for holding source material to be deposited, such as the source material 280 of FIG. 2.

Generally, the crucible body 525 forms at least one intermediate orifice between the source material and the emitting orifice 520. In the example shown in FIG. 5, the crucible body forms at least a first, second, and third intermediate orifices 532, 534, 536. Typically, the region of the crucible body 525 forming the intermediate orifice 532, 534, 536 is deformed radially inwardly (i.e., towards longitudinal axis C). In a preferred embodiment, the intermediate orifice region of the crucible body 525 curves inward as indicated at 532, 534 of FIG. 5. Of course, this region can also extend linearly inwardly at an angle from the rest of the crucible body 525.

In one embodiment, the entire circumference of the intermediate orifice region tapers inwardly (radially) towards the central longitudinal axis C as shown at 536. In another embodiment, only a portion of the circumference of the intermediate orifice region tapers inwardly as shown at 534 (thereby providing an off-center intermediate orifice). As an example, compare the third intermediate orifice 536, the entire circumference of which extends inwardly, with the first and second intermediate orifices 532,534, of which only a portion of the circumference curves inwardly. In yet another embodiment (not shown), one portion of the circumference may extend inwardly towards the longitudinal axis C to a lesser degree than another portion, thereby providing an off-center intermediate orifice.

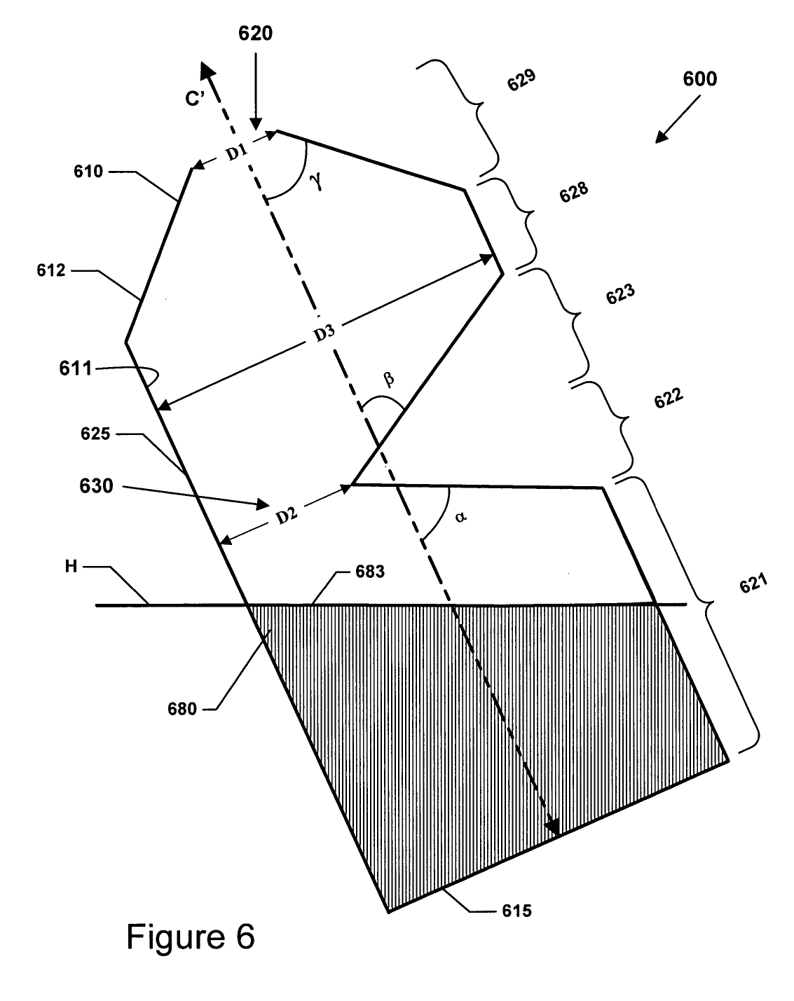

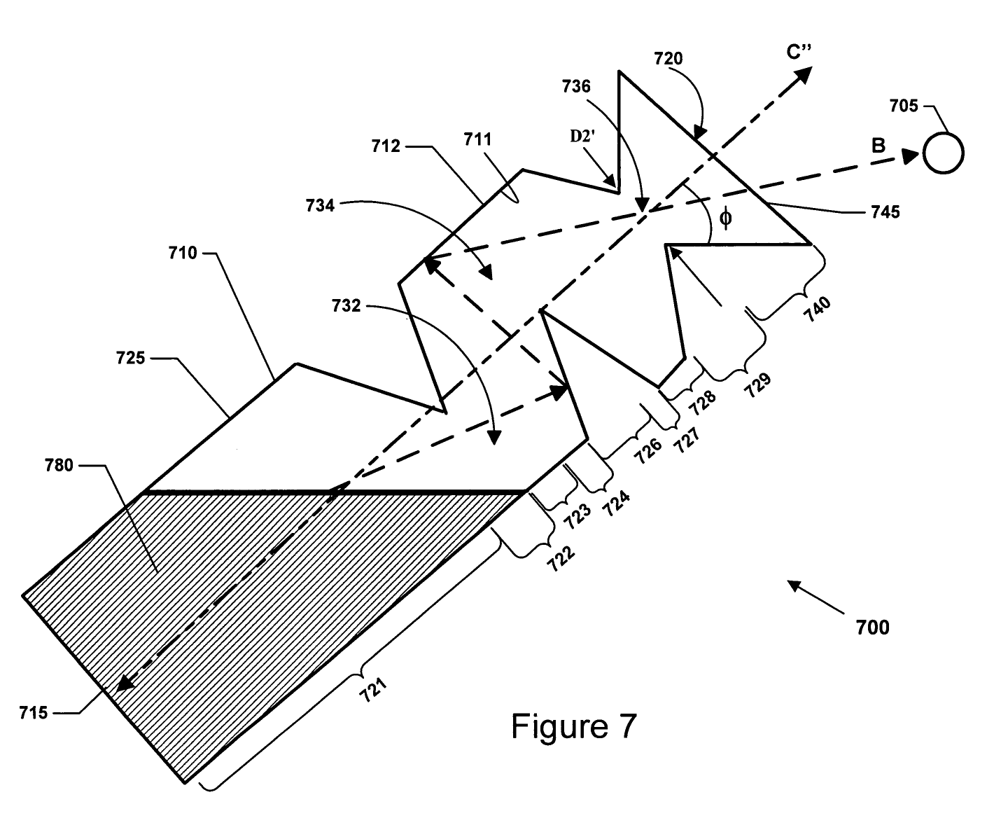

Referring to FIGS. 6 and 7, some of the principles of the present invention can best be shown using cross-sectional diagrams of example embodiments of crucibles configured according to the principles of the present invention. FIG. 6 illustrates a schematic cross-sectional view of one example embodiment 600 of a crucible 610 configured according to the principles of the present invention. The crucible 610 includes a body 625 extending from a base 615 and terminating at an emitting orifice 620. In this example embodiment, the body 625 of the crucible 610 forms a single intermediate orifice 630 between the base 615 and the emitting orifice 620.

The crucible 610 houses source material 680 proximate the base 615. In operation, the crucible 610 is generally tilted along a longitudinal axis C″. FIG. 6 illustrates the source material 680 arranged within the crucible 610 so that a surface 683 of the source material 680 lies in a horizontal plane H. When heated, the source material 680 vaporizes and the vaporized atoms and/or molecules, such as molecules 305, 305′ of FIGS. 3 and 4, travel through the intermediate orifice 630 and towards the emitting orifice 620.

The crucible body 625 has an inner surface 611 and an outer surface 612. In general, the intermediate orifice 630 is sized and oriented such that the vaporized atoms and/or molecules of source material 680 are manipulated into impinging upon the inner surface 611 of the crucible body 625 at least once before passing through the emitting orifice 620. This impingement is effectively accomplished by removing all line of sight travel paths from the surface 683 of the source material 680 to the target substrate as seen through the emitting orifice 620.

The crucible body 625 includes a generally cylindrical base section 621 about the axis C′ and proximate the base 615, and a first negative draft tapered portion 629 proximate the emitting orifice 620. In some embodiments, the intermediate orifice 630 is formed by a second negative draft portion 622 of the body 625 continuously connected with a first positive draft portion 623 of the body 625. The second negative draft portion 622 extends inwardly towards the central longitudinal axis C′ from the base section 621. The first positive draft portion 623 extends outwardly from one end of the negative draft portion 622. In some embodiments, sections of the crucible body formed between the negative draft portions and the positive draft portions, such as section 628, are generally cylindrical about the central axis C.

In some embodiments, the negative and positive draft portions 622, 623, 629 of the crucible body 625 taper at draft angles α, β, γ, respectively. In general, the draft angles α, β, γ range from about 10° to about 90° with respect to the longitudinal axis C. In some example embodiments, the draft angle α, β, γ range from 30° to about 45°. In one preferred embodiment, the first negative draft portion 629 tapers inwardly at an angle γ about 45° with respect to the longitudinal axis C, the second negative draft portion 622 tapers inwardly at an angle α of about 30°, and the first positive draft portion 623 tapers outwardly at an angle β of about 30°. Of course, since the tapered draft portions, such as tapered draft portions 622, 623, 629, can be rounded or straight, the draft angles discussed above are merely approximations and can change along the length of the draft portions.

In the example shown in FIG. 6, the emitting orifice 620 of crucible 610 has a diameter D1, the intermediate orifice 630 has a diameter D2, and the crucible body 625 has a diameter D3. Consequently, the emitting orifice 620 of the crucible 610 has a cross-sectional area of approximately A1, wherein:

$$A 1 = {π ( \frac{D 1}{2} )}^{2}$$

Similarly, the intermediate orifice 630 and the crucible body 625 have cylindrical cross-sectional areas A2, A3, respectively, wherein:

$$A 2 = {π ( \frac{D 2}{2} )}^{2} ;$$

$$A3 = {π ( \frac{D 3}{2} )}^{2}$$

In various embodiments, the cross-sectional area A2 of the intermediate orifice 630 can be greater than, equal to, or less than the cross-sectional area A1 of the emitting orifice 620. In some embodiments, the cross-sectional area A1 of the emitting orifice 620 and the cross-sectional area A2 of the intermediate orifice 630 are significantly less than the cross-sectional area A3 of the crucible body 625. In a preferred embodiment, the cross-sectional area A1 of the emitting orifice 620 is about 0.6 inches² (3.8 cm²), the cross-sectional area A2 of the intermediate orifice 630 is about 0.5 inches² (3.2 cm²), and the cross-sectional area A3 of the crucible body 625 is about 1.1 inches² (7.3 cm²).

Referring now to FIG. 7, another example embodiment 700 of a crucible configured according to the principles of the invention is shown. FIG. 7 illustrates a schematic cross-sectional view of a crucible 710 including a body 725 extending from a base 715. The crucible body 725 forms an emitting orifice 720, a first intermediate orifice 732, a second intermediate orifice 734, and a third intermediate orifice 736. The body 725 houses source material 780 proximate the base 715.

The crucible 710 further includes a neck portion 740 extending between the third intermediate orifice 736 and the emitting orifice 720. The intermediate orifice 736 defined by one end of the neck portion 740 is referred to as a neck orifice. An opposing end of the neck portion 740 includes an annular lip 745 forming the emitting orifice 720. In some embodiments, the annular lip 745 can extend outwardly from the terminal edge of the body 725, preferably at a right angle thereto.

Some embodiments of the neck section 740 of the crucible body 725 include a positive draft portion extending away from the neck orifice 736 at a positive draft angle relative to a longitudinal axis C″ and terminating at the emitting orifice 720. In one embodiment, the neck portion 740 tapers outwardly away from the central longitudinal axis C″ of the crucible body 725 at a preferred angle of about 9.0 degrees.

In general, by eliminating the line of sight from any portion of the source material, such as source material 780, to the target substrate and by adjusting the shape and orientation of the last section of the inner surface of the crucible body that has direct line of sight to the substrate, the probabilities of paths of where the atoms and molecules of the vaporized source material are aimed can be adjusted. For example, the intermediate orifices 732, 734, 736 of crucible 710 are arranged and configured such that atoms and molecules vaporized from the source material 780 must impinge upon the inner surface 711 of crucible body 725 before exiting from the emitting orifice. In particular, the vaporized source material bounces off of at least one of sections 722, 723, 726, 727, 729, 740 of the crucible body 725 at least once before reaching the emitting orifice 720.

Atoms and molecules, do not “bounce” off a crucible surface as rubber balls would, but rather are adsorbed and desorbed from the surface. For example, a path B of an atom 705 is shown in FIG. 7 as the atom 705 “bounces” (i.e., adsorbs and desorbs) from the inner surface 711 of the crucible body 725 before leaving the crucible 710. First, the atom 705 “bounces” off of the inner surface 711 of a negative draft portion 726 of the body 725. Second, the atom 705 “bounces” off of the inner surface 711 of cylindrical portion 724 of the crucible body 725. Of course, the path B taken by atom 705 is exemplary only, and many other paths could be taken, including paths which return the atom or molecule to the source material 780.

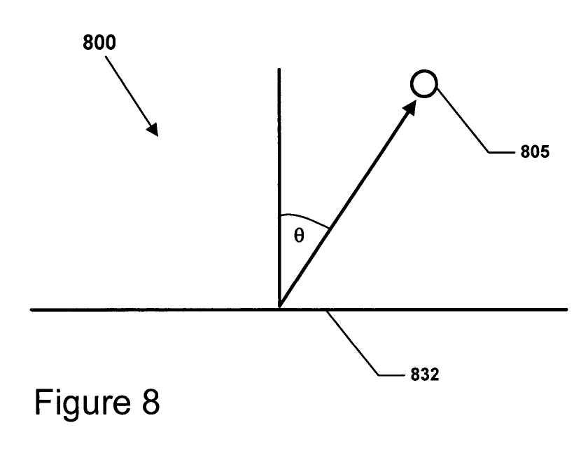

Referring now to FIG. 8, the angle at which atoms and molecules are desorbed from a surface (e.g., the inner surface of the crucible or the surface of the source material) is not random. FIG. 8 illustrates a schematic diagram of a system 800 in which an atom 805 desorbs from a surface 832 at an angle θ. In general, the cosine function, ξ=cos(θ)/π, can be used to approximate the probability ξ that an atom or molecule, such as atom 805, will desorb at a given angle θ. Theoretically, the angle θ with the highest probability ξ is a ninety-degree angle perpendicular to the inner surface of the crucible. In conventional crucible systems, such as the crucible 110 of FIG. 1, therefore, the atoms and molecules are most likely to evaporate straight up from the source material surface in a direction parallel to the longitudinal axis of the crucible.

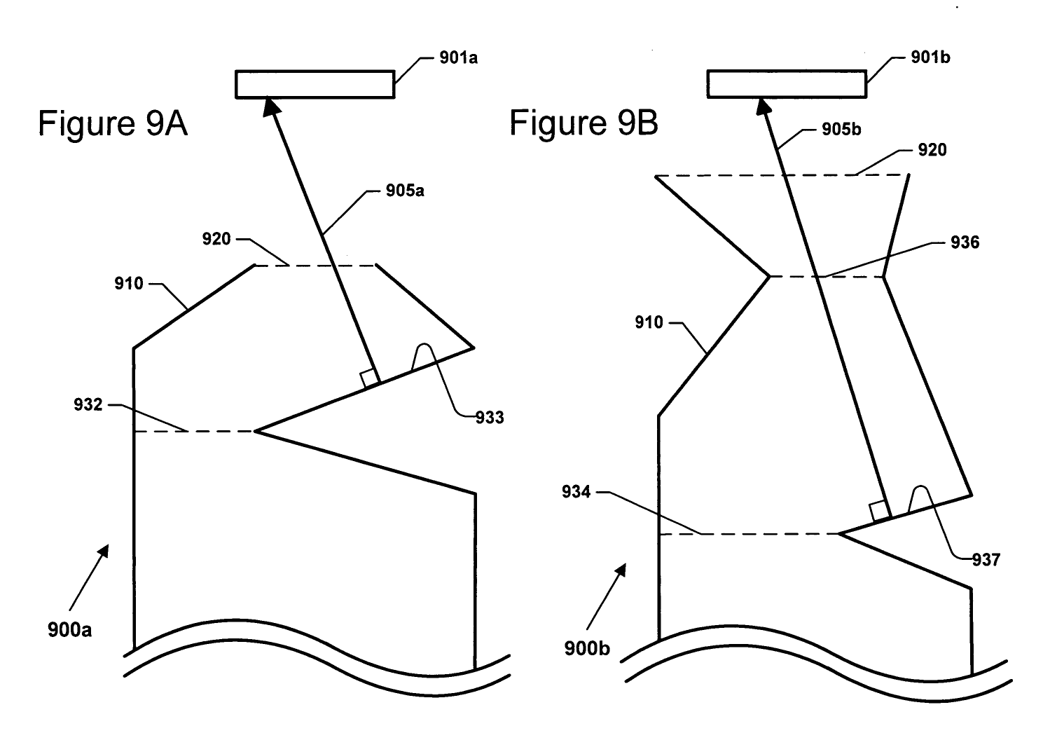

Referring now to FIGS. 9A and 9B, in some embodiments of crucibles implementing the present invention, the last surface which has direct line of sight to the target substrate is a surface of an intermediate orifice. FIGS. 9A and 9B illustrate cross-sectional diagrams of systems 900a, 900b, respectively, depicting the highest probability of desorption from first and second surfaces 933, 937, respectively. For example, the first surface 933 is an inner surface of a positive draft portion of a crucible forming an intermediate orifice 932. As another example, the second surface 937 is an inner surface of a positive draft portion forming an intermediate orifice 934.

Referring to FIG. 9A, in some embodiments, the last surface having direct line of sight to the target substrate is a surface of an intermediate orifice nearest the emitting orifice. For example, the first surface 933 forming the intermediate orifice 932 has direct line of sight to a target substrate 901a. Intermediate orifice 932 is the intermediate orifice nearest the emitting orifice 920. Referring to FIG. 9B, in some embodiments, a second intermediate orifice 936 is located between the emitting orifice 920 and the last surface 937 having direct line of sight to a target substrate 901b.

Generally, increasing the number of crucible body surfaces blocking the line of sight from the vaporized source material to the target substrate increases the number of surfaces upon which the vaporized source material must absorb and desorb. Each contact between the molecules and the crucible body enables a transfer of thermal energy from the crucible surface to the molecule. If sufficient thermal energy is transferred, the bonds holding the atoms of the molecule together can be broken. Breaking these bonds increases the likelihood that large polyatomic molecules will “crack” into smaller molecules (e.g., one As₄ will break into two As₂ molecules).

Large particles, such as the particles 407 of FIG. 4, are unlikely to “crack” after leaving the crucible due to a low probability of the particles bouncing off of each other (i.e., adsorbing and desorbing one another) within the vacuum growth chamber. The average distance a molecule or atom would need to travel before encountering another molecule is often referred to as the mean free distance. A formula for calculating the mean free distance of a molecule in a vacuum is listed below:

$$λ = \frac{kT}{{2}^{1 / 2} P σ}$$

where: λ is the mean free distance, k is Boltzmann's constant (i.e., 1.38×10⁻²³ J/K), T is the temperature of the chamber, P is the pressure within the chamber, and σ is the cross sectional area of the molecule. A typical MBE growth chamber is less than 2 m across. The temperature inside a growth chamber is generally around room temperature (i.e., approximately 273 K). The pressure inside a growth chamber is generally very low. Typically, the pressure within a growth chamber is less than 10⁻⁹ Torr (i.e., 1.33×10⁻⁷ N/m²).

In general, the cross sectional area of atoms can be considered to be relatively constant. Typically, a cross sectional area of an atom ranges from about 3.0×10⁻²¹ m² (e.g., a helium atom) to about 2.8×10⁻¹⁹ m² (e.g., a cesium atom). Nitrogen, which is the most abundant atom in typical MBE systems, has a cross sectional area of about 9.8×10⁻²¹ m². The mean free distance of a helium atom in a growth chamber “full” of helium (i.e., a growth chamber in which the pressure and temperature are about normal) can be approximated, therefore, to be about 6,676,577 m. Such a large mean free distance contributes to the low probability of the atoms and molecules within the vacuum growth chamber encountering one another before reaching the substrate.

As mentioned above, in some conventional crucible systems a baffle is inserted within the crucible to increase the likelihood of cracking large molecules. In some conventional systems, the baffle is heated via conduction or radiation from an outer surface of the crucible and, hence, typically has a lower temperature than the crucible. A lower temperature reduces the amount of thermal energy transferred to the molecule upon impact and, thereby, reduces the probability that a polyatomic molecule will crack into a simpler molecule.

Referring now to the present invention, in general, the tapered draft portions of the crucible body, such as crucible body 525 of FIG. 5, are directly heated by the crucible-heating element. Directly heating the tapered draft portions enables more efficient heating of the inner surfaces upon which the molecules of vaporized source material will adsorb and desorb. More efficient heating increases the probability that thermal energy will be transferred to the molecules and, hence, that the molecules will crack.

In general, the crucibles are formed by a chemical vapor deposition (CVD) process utilizing a forming mandrel in a vacuum chamber. In some example embodiments, a crucible is formed of an inert, corrosion resistant material. A preferred forming material is pyrolytic boron nitride (i.e., PBN). The thickness of PBN for the crucible is typically about 0.035 inches (0.08 cm). In various other example embodiments, the crucible can be formed from quartz, AlN, SiC, tungsten, and tantalum.

In general, the crucible ranges in length from about 1 inch to about 25 inches. The diameter of the crucible varies along the body. The diameter of the base of the crucible generally ranges from about 0.5 inches (cm) to 8.0 inches. In one example embodiment, the crucible, such as the crucible 510 of FIG. 5, is about 14.5 inches (36.8 cm) in length and the base of the crucible is about 1.4 inches (3.5 cm) in diameter. In another example embodiment, the crucible has a length of about 8.1 inches (20.5 cm), a widest diameter at the base of about 2.9 inches (7.3 cm), and a narrowest diameter at an intermediate orifice of about 0.9 inches (2.2 cm).

In some embodiments, each orifice has a peripheral dimension, such as peripheral dimension P of orifice 520 in FIG. 5. In one example embodiment, the peripheral dimension of an orifice is about 0.7 inches (1.8 cm). In one example embodiment, the length of the neck section of a crucible body, such as neck section 740 of crucible body 725 of FIG. 7, is about 2.3 inches (5.8 cm). In this example embodiment, the emitting orifice has a preferred diameter of about 1.5 inches (3.8 cm). In another embodiment, an annular lip of a neck section has a width of about 0.8 inches (2.0 cm). Of course, any suitable crucible dimensions may be used consistent with the basic teachings of the invention.

The crucibles discussed herein with reference to FIGS. 5-7, can be used within an MBE system, such as the MBE system 200 of FIG. 2. In some example embodiments, the crucible is used with an effusion assembly (not shown). Generally, an effusion assembly includes a head assembly attached to a support assembly. In one example embodiment, the support assembly includes at least one support post extending from a mounting flange. The head assembly includes the crucible and at least one heater. In another example embodiment, the effusion cell further includes heat shielding, at least a portion of which extends inwardly and terminates in the vicinity of a neck orifice. In yet another example embodiment, the effusion cell further includes an integral water-cooling system.

The above specification, examples and data provide a complete description of the manufacture and use of the composition of the invention. Since many embodiments of the invention can be made without departing from the spirit and scope of the invention, the invention resides in the claims hereinafter appended.

We claim:

1. A crucible for heating material to be deposited on a substrate, the crucible comprising:
a body including a base, the body arranged and configured to contain source material,
an emitting orifice formed at an end of the body, the emitting orifice shaped and oriented to enable heated source material to exit the crucible; and
at least one intermediate orifice formed by the body, the intermediate orifice arranged and configured to cause a significant portion of the heated source material to pass through the intermediate orifice and to impact at least once upon an inner surface of the body before passing through the emitting orifice.

2. The crucible of claim 1, wherein the intermediate orifice is arranged and configured to cause all of the heated source material impacts at least once upon an inner surface of the body before passing through the emitting orifice.

3. The crucible of claim 1, wherein the crucible is monolithically formed.

4. The crucible of claim 1, wherein the body forms at least a first and second intermediate orifice.

5. The crucible of claim 4, wherein one of the intermediate orifices is a neck orifice and the body has a negative draft angle extending away from the neck orifice and terminating at the emitting orifice.

6. The crucible of claim 4, wherein the first intermediate orifice has a first peripheral dimension and the second intermediate orifice has a second peripheral dimension, the second peripheral dimension being greater than the first peripheral dimension.

7. The crucible of claim 4, wherein the intermediate orifices are arranged and configured to cause the portion of the heated source material to impact upon the inner surface of the crucible body multiple times before passing through the emitting orifice.

8. The crucible of claim 1, wherein the crucible is formed from one of the group consisting of pyrolytic boron nitride, quartz, tungsten, tantalum, aluminum nitride, and silicon carbide.

9. The crucible of claim 1, wherein the crucible is formed via negative draft molding.

10. A method for heating material to be deposited on a substrate, the method comprising:
providing a crucible including a body arranged and configured to contain source material, the body forming a base at a first end of the body, an emitting orifice at a second end of the body, and at least one intermediate orifice intermediate the base and the emitting orifice;
placing source material within the crucible; and
heating the crucible, wherein heating the crucible heats the source material, and
wherein the body forming the intermediate orifice is arranged and configured such that a portion of the heated source material impacts upon an inner surface of the body at least one before exiting the crucible through the emitting orifice.

11. The method of claim 10, further comprising:
providing a second crucible;
placing source material within the second crucible; and
heating the second crucible.
